(19) United States
(12) Patent Application Publication
(10) Pub. No.: US 2011/0052828 A1
(43) Pub. Date: Mar. 3, 2011

(54) Method for high-temperature ceramic circuits

(76) Inventors: Randy Allen Normann, Edgewood, NM (US); Joseph Anthony Henfling, Bosque Farms, NM (US)

(21) Appl. No.: 12/584,342

(22) Filed: Sep. 3, 2009

(51) Int. Cl. H05K 3/00

(52) U.S. Cl. 427/446; 427/96.1

(57) ABSTRACT

A novel means for placing conductive metal traces on ceramic without adhesives, glues or any organic materials. Metal traces created by thermal spraying metal on to a prepared ceramic surface. The ceramic surface is prepared by creating recesses where the metal is to remain as circuit traces. Following thermal spray, the excess metal is removed from the surface leaving the metal electrically conductive traces in the ceramic recesses. This process improves metal to ceramic bond, reducing failures caused from thermal expansion differences between ceramic and metal traces and eliminates all organic adhesives.

### GOVERNMENT INTERESTS

Part of this invention was developed under Contract DE-AC04-94AL8500 between Sandia Corporation and the U.S. Department of Energy. The U.S. Government has certain rights in this invention.

The remaining parts of this invention were developed under award number DE-FG36-08GO18185 between Perma Works LLC and the U.S. Department of Energy. The U.S. Government has certain rights in this invention.

### BACKGROUND OF THE INVENTION

1. Technical Field of the Invention

A means for creating conductive metal traces on or in ceramic for the purposes of creating electronic circuits.

2. Description of Prior Art

Ceramic materials have been used for building circuit boards for more than 20 years. Ceramics have a very good thermal expansion coefficient for mounting silicon chips (bare integrated circuits). As such, ceramic circuit boards are used in multi-chip-modules (MCM) to build reliable electronic circuits which can operate over a board range of temperatures.

Current technology used to place conductive traces onto ceramic uses LTCC (low temperature co-fired ceramic) process. Here the metal traces are placed into the green (unfired) ceramic by silk screening a paste of metal particles held in an organic binder. With the traces are in place, the ceramic and traces are co-fired, normally >900° C. This process cures the ceramic and bakes off the organic material while the metal particles fuse (center) to each other and the surface of the ceramic. The end result is metal traces on a ceramic board without any organic glues or adhesives. In general, LTCC yields a circuit board able to survive to temperatures greater than 300° C.

The process of LTCC is limited to approximately 4 inch board sizes. Metal traces running more than 4 inches may fail to bond to the surface of the ceramic during the co-firing, as curing ceramic has a higher percentage of shrinkage than the metal trace.

Once cured, the ceramic has far less thermal expansion than the metal trace. So, during high-temperature circuit operations the temperature cycling of the LTCC assembly is prone to failure. This is particularly true of power circuits which require thick metal traces. The thickness of the metal traces greatly increases the strain between the metal trace and the ceramic bond.

Patent Application 20060027374. Electrical transmission system, Ludlow; Jeremy Leonard Clive; (Hampshire, GB); Maylin; Mark Gregory; (Hampshire, GB); Rogers; Michael Clive; (Hampshire, GB). This invention relates to a process allows protective coatings against high temperature inside conductive pipelines as in oil and gas. Here a thermal spray of non-conductive protective ceramic is applied to the pipe. After such application a second thermal spray of conductive materials can be applied using a mask to create conductive traces. A third layer of thermal spray of non-conductive material is applied to protect the conductive traces. This process offers a unique cable construction for creating signal paths on top of conductive surfaces such as pipes use in the oil industry. Our process starts with machined or etched ceramic base constructed uniquely for fine detailed circuit board traces needed for mounting an unlimited number of integrated circuits. Our process is unique in its application and construction enabling the use of any ceramic material and embedded traces.

U.S. Pat. No. 5,089,881. Fine-pitch chip carrier, Panicker; Ramachandra M. P. (Camarillo, Calif.). This is a variation on standard processes, a thin-film metallization deposited on the upper surface of ceramic substrate by use of the photolithographic process, said thin-film metallization patterned to provide signal, ground and power bonding pads to mount the IC chip and conductive traces for connecting each of the signal metal filled vias to one of the signal bonding pads I constant with current technology. Our process removes the need for deposited thin-film processes.

U.S. Pat. No. 7,413,846. Fabrication methods and structures for micro-reservoir devices, Maloney, et al. This invention is using standard methods for creating conductive traces (photoresist, sputtering) on ceramic surfaces connecting recesses or reservoirs loading each reservoir with reservoir contents (such as a drug or sensor). This invention uses conventional methods to create conductive circuit traces and uses voids or reservoirs in the ceramic for housing drugs or sensors.

### SUMMARY OF THE INVENTION

Plasma (electrical arc) spray, flame spray or high velocity impact processes can be used to create metal surfaces on ceramic without organic materials or high-temperature co-firing. As such, this process allows the use of completely fired ceramic before placing the conductive traces onto the board. This also allows the use of any type of ceramic, even very high-temperature ceramic such as silicon-carbide. Once the ceramic is coated with a layer of conductive metal, it can be worked like any standard circuit board material. In standard (very low cost) circuit board manufacturing unwanted metal is removed using a chemical process. However, any machining process could also be used.

A slight variation of the new proposed process is to etch (using photochemical, ultrasonic or combination of processes to etch ceramic) the ceramic to leave either low depressions or complete cutaways where conductive metal traces are needed. After the stock board is etched for circuit connections and traces, the metal layer can now be applied. To remove unwanted metal, any number of mechanical or chemical processes (including simple sanding), can be used to remove the upper metal layer leaving conductive metal traces in etched sections.

This process yields five benefits over LTCC process.

1. Plasma (electrical arc) spray, flame spray or high velocity impact processes are faster and less expensive than silk screening used in the LTCC process.

2. Placing conductive metal traces in etched ceramic allows for the metal to attach to the ceramic on three sides. Such a configuration allows higher bonding strengths between the ceramic and the metal traces allowing for improve operating life times for applications with temperature cycling. Greater bonding allows for heavier metallization for improved current carrying capability.

3. Placing the metal on the ceramic after the ceramic is fired allows for unlimited board and trace sizes.

4. Placing a metal layer on ceramic without the use of co-firing, allows for the use of any ceramic material with any conductive metal. Silicon carbide ceramic is fired at temperatures above 1600 C, too hot for LTCC. Silicon-Carbide (SiC) is one of the strongest ceramics and has the best heat dissipation factor, higher than carbon steel.

5. By eliminating any organic material from the circuit, significantly reduces the aging process when operated at temperatures over 200° C. At elevated temperatures, organic materials break down or decompose.

### BRIEF DESCRIPTION OF THE DRAWINGS

FIG. 1. (A1) Is a sample ceramic board with two long sample traces, 1a and 2a. In general, these traces can be any dimension and be applied to both sides of the board. Not shown but common to circuit boards are pads for connecting to components, via for connecting traces to traces on the opposite sides of the board. The subfigures B1, B2 and B3 illustrate by showing a cut through of the board during the processes which were used to create these traces in the ceramic.

FIG. 2. Is a three step illustration outlining the basic process of this invention. (B1) is showing a cut through of the board in figure A1 prior to placement of the metal layer. (B2) Illustrates the board and applied metal layer filling the recesses. (B3) Illustrates a finished product with trace 1c being flat to the ceramic surface. Trace 2c is allowed to be raised above the board surface.

FIG. 3 is a photo showing the process converted to practice. The conductive traces (light color) are all that remains of the metal after the exposed surface metal was sanded away. The connective traces around the each hole will allow for successful soldering of circuit device leads needed to complete the circuit.

### DETAILED DESCRIPTION OF THE PRESENT INVENTION

This invention allows for the creation of electronic circuits to be manufactured as electrically conductive recesses in a non-conductive material as ceramic.

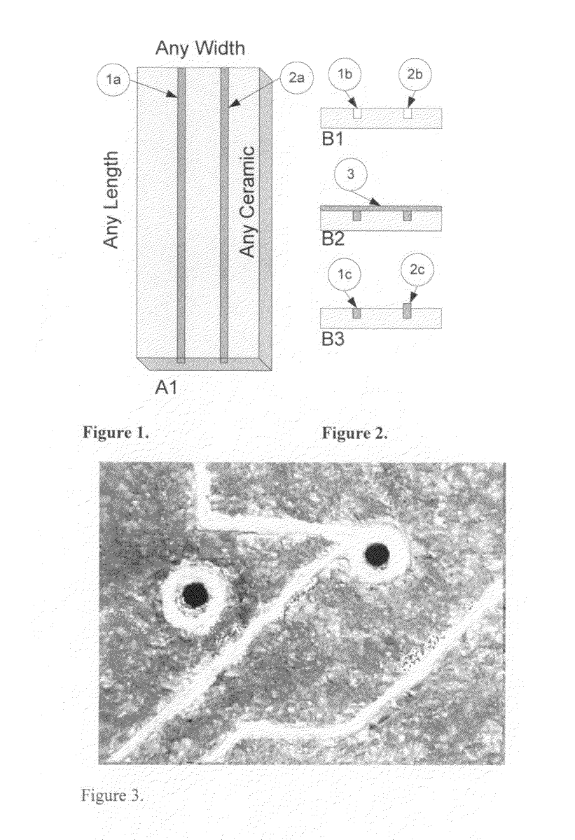

Under work conducted at Sandia National Labs by the inventors Joseph Henfling and Randy Normann, the process of creating a metal layer onto a clean ceramic surface was demonstrated as illustrated in FIG. 1.

FIG. 1 illustrates that there are no size limitations in length, width of the conductive traces. Our process allows for the metal conductor to be placed on the ceramic after the ceramic has been cured.

Under work conducted under DOE grant to Perma Works LLC, inventor Randy Normann developed the concept illustrated in FIG. 2 to commercial practice shown in FIG. 3. FIG. 2 illustrates an example creation of two conductive traces on non-electrically conductive ceramic. The invention is the construction of any number of conductive traces, mounting pads and interconnecting via within manufactured recesses in a nonconductive material as ceramic by method of metal particle thermal spray or high velocity impact. Under these conditions, metal particles impact the ceramic creating a metal to ceramic bond without use of glues or adhesives. No organic material is used during this process.

The use of silicon carbide ceramic for the creation of nonconductive base material shown in FIG. 1 where silicon carbide ceramic has greater thermal conductivity than alumina ceramic or any other LTCC compatible ceramic. The process for creating recesses in silicon carbide is performed by first creating a carbon (C) base. The carbon base is then machined or molded or pressed in to shape containing circuit element recesses. However, carbon is a conductor and can not be used as board material. The carbon base is then exposed to silicon gas at >1000° F. elevated temperatures creating silicon carbide ceramic. Silicon carbide is a non-conductor of electricity. At this point, the silicon carbide is ready for metallization as show in FIG. 2.

There can be any number of repeated metallization processes of thermal spray or impacted spray such that increases thickness of the metal traces. Other type of metallization can be applied as a second or third layer. As such, a base material of nickel (poor conductor) could have a second layer of copper (good conductor).

After the first layer of metallization is applied by thermal spray or other high impact process, a second pass of molten metal could be applied. The molten metal could be pored into the metal filled recesses and wiped away from the ceramic surface. This process would better fill in the pours left by the spraying process. As such, a thermal spray of nickel particles could be followed by a lower temperature melting conductor as copper.

We claim:

1. A method for creating circuit board conductive elements (traces, pads, via, solder points, mounting holes, etc) comprising the steps of: using thermal spray, plasma spray or high velocity impact of conductive metal particles on to nonconductive ceramic.

2. A method according to claim 1, wherein the removal of excess material resulting from thermal spray, plasma spray or high velocity impact of conductive material is removed by chemical or machining processes.

3. A method according for creating conductive circuit elements comprising the steps of: using recesses in the nonconductive base material prior to applying a metal coating; and then removing the metal coating at the surface.

4. A method according to claim 3, wherein the recesses are created by pressure molding unfired ceramic.

5. A method according to claim 3, where the recesses or holes are created using supersonic milling.

6. A method according to claim 3, where the recesses or holes are created using mechanical milling processes.

7. A method according to claim 3, where additional passes of thermal spray or applied molten metal are used to increase trace depth or add additional types of metal conductors.

8. A method for creating recesses for conductive circuit elements in silicon carbide ceramic comprising the steps of: first creating a carbon (C) base material with imposed recesses for conductive circuit elements; and then using exposure to high-temperature silicon gas to transform the carbon base board to silicon carbide (SiC).

9. A method according to claim 8, wherein a mold or press is used to create the circuit element recesses in the carbon material.

10. A method according to claim 8, wherein the recesses are created by pressure molding the carbon base material.

11. A method according to claim 8, where the recesses or holes are created using supersonic milling of the silicon carbide.

12. A method according to claim 8, where the recesses or holes are created using mechanical milling processes in the carbon base material.

13. A method according to claim 3, where the circuit board and semiconductor devices are mounted on to pipes containing hot solar heated fluids to allow for the transfer of self generating heat of the semiconductor devices to the solar heated fluid.

14. A method according to claim 3, where the circuit board and semiconductor generated heat is used to generate power in a solar-thermal power plant.
